(19) United States
(12) Patent Application Publication
(10) Pub. No.: US 2008/0318392 A1
(43) Pub. Date: Dec. 25, 2008

(54) SHALLOW TRENCH ISOLATION STRUCTURE AND METHOD FOR FORMING THE SAME

(75) Inventors: Kuo-Hsiang Hung, Changhua County (TW); Chuan-Chi Chen, Jhubei City (TW)

Correspondence Address: HOLLAND & KNIGHT LLP, 10 ST. JAMES AVENUE, 11th Floor, BOSTON, MA, 02116-3889, US

(73) Assignee: Promos Technologies Inc., Hsinchu (TW)

(21) Appl. No.: 11/864,037

(22) Filed: Sep. 28, 2007

(30) Foreign Application Priority Data
Jun. 23, 2007 (TW) 096122740

(51) Int. Cl. H01L 21/76

(52) U.S. Cl. 438/435; 438/422; 257/E21.54

(57) ABSTRACT

A method for forming shallow trench isolation structures is provided. The method comprises the following steps: providing a substrate with a “v” shaped trench, forming a first dielectric layer to cover the upper portion of the inner wall of the trench; conducting the first etching process to pull back the uncovered inner wall of the trench; removing the first dielectric layer; and forming a second dielectric layer to cover the trench and form a void inside the trench.

### RELATED APPLICATION

This application claims priority to Taiwan Patent Application No. 096122740 filed on 23 Jun. 2007.

### BACKGROUND OF THE INVENTION

1. Field of the Invention

The present invention relates to a method for forming a shallow trench isolation structure with a void that can release structural stress during fabrication of a semiconductor element.

2. Descriptions of the Related Art

Currently, in fabricating high-transistor-integrity semiconductor elements, transistors are usually isolated by shallow trench isolation. The steps of forming the shallow trench isolation are illustrated in FIGS. 1A to 1F. In FIG. 1A, a pad oxide layer 13 and a pad nitride layer 15 are sequentially formed on a base layer 11, wherein the pad oxide layer 13 can be formed using a thermal oxidation process and the pad nitride layer 15 can be formed using a low pressure chemical vapor deposition (LPCVD) process. Then, a patterned photoresist layer 17 with an active area pattern is formed on the pad oxide layer 15.

In FIG. 1B, a portion of both the pad oxide layer 13 and the pad nitride layer 15, which are unprotected by the patterned photoresist layer 17 on the base layer 11, are removed by a dry etching process to expose a portion of the base layer 11. After that, as shown in FIG. 1C, the patterned photoresist layer 17 is removed and a portion of the exposed portion of the base layer 11 is removed by a dry etching process to form a trench 19 with a proper depth.

FIG. 1D illustrates the trench filling process. Herein, before trench filling, a thermal oxidation process is usually conducted to form a thin oxide layer, called a liner oxide 21, on the inner wall of the trench 19. Thereafter, silicon oxides 23 (SiO₂) are deposited and filled into the trench 19 using a suitable deposition method, such as the LPCVD. Finally as shown in FIG. 1E, a chemical mechanical polishing (CMP) process is conducted to remove the unnecessary silicon oxides 23. Thereafter, a wet etching process is conducted to remove both the pad oxide layer 13 and pad nitride layer 15. As a result, a shallow trench isolation structure is created.

The quality of the above-mentioned trench filling process affects the isolation of the shallow trench isolation structure. If a method with poor step coverage is used in the trench filling process or the trench has a high aspect ratio, a non-conformal deposition resulting from the trench filling process will create an overhang in the deposition layer. As a result, a void 25 is created within the trench, as shown in FIG. 1F. If the void 25 lies near the surface of the base layer 11, a hole 27 appears on the surface of the shallow trench isolation structure after the process, illustrated in FIG. 1E, is conducted. The hole 27 may be filled with conductive materials during other processes that occur thereafter, resulting in short circuits between the word lines.

The industry has developed several solutions to avoid the foregoing short circuit problem caused by the hole 27, which is generated during the trench filling process. For example, a spin on glass (SOG) coating method has been proposed, in which silicon dioxides with high fluidity flow into and fill up the trench. An etching process has also been proposed, in which a portion of the filled silicon oxide is removed during the filling process to reduce the effect of the non-conformal deposition when the silicon oxide is deposited. Then, the deposition process is conducted again for the remaining silicon oxide. Yet another example is disclosed in U.S. Pat. No. 6,861,333, in which an oxide layer is formed on the bottom of the trench to reduce the aspect ratio of the trench before the trench filling process is conducted.

Although the above-mentioned solutions prevent the formation of a void in the trench, they are all complicated processes that have high costs. In addition, it has been found that if voids are created in certain positions within the trench, they can actually reduce the internal stress created within the base layer during fabrication of the high-transistor-integrity semiconductor elements. Thus, it is important for the industry to provide a method for forming a shallow trench isolation structure, in which a hole is not formed on the surface thereof, but in a particular position to reduce said internal stress.

### SUMMARY OF THE INVENTION

The primary objective of this invention is to provide a method for forming a shallow trench isolation structure. The method comprises the following steps: providing a substrate and forming a “v” shaped trench within the substrate; forming a first dielectric layer to cover the upper portion of the inner wall of the trench; conducting the first etching process to pull back the inner wall, which is uncovered by the first dielectric layer, of the trench; removing the first dielectric layer; and forming a second dielectric layer to cover the trench and to form a void inside the trench.

Another objective of this invention is to provide a shallow trench isolation structure comprising the following: a substrate with a trench, wherein the trench has a waist whose width is narrower than that of the opening of the trench; a second dielectric material covering the opening of the trench; and a void inside the trench.

According to the disclosed technique of the invention, the shallow trench isolation structure has a void in a suitable position to reduce stress and prevents short circuiting from occurring between the word lines.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A to FIG. 1E illustrate the formation of shallow trench isolation structures in accordance with the prior art;

FIG. 1F illustrates a harmful void formed in a known process of forming a shallow trench isolation structure;

FIG. 1G illustrates a harmful hole on the surface of the known shallow trench isolation structure; and

FIG. 2 to FIG. 6D illustrate the process of forming a shallow trench isolation structure with a suitable void according to the present invention.

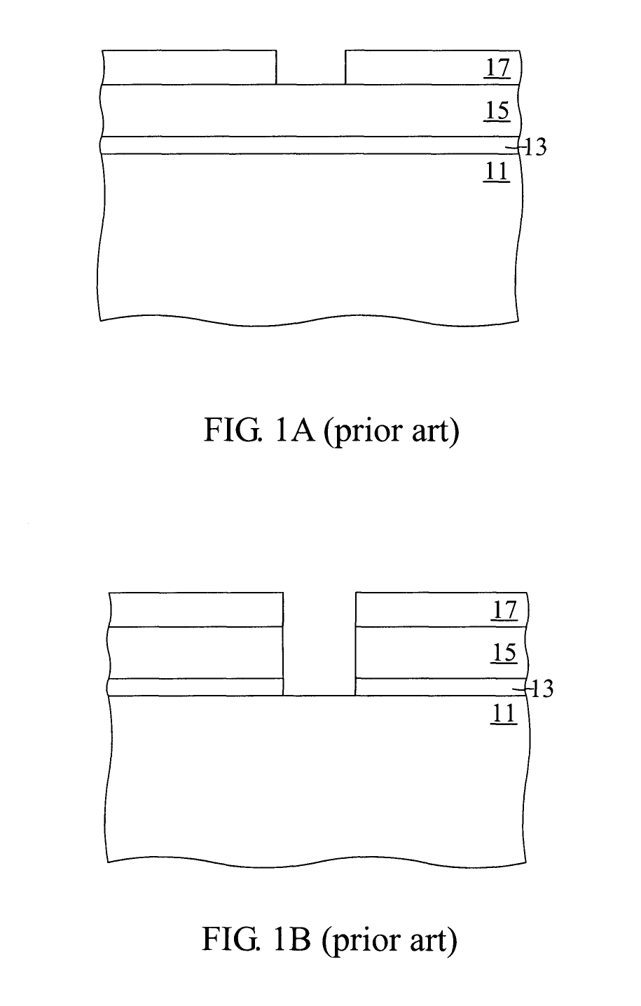

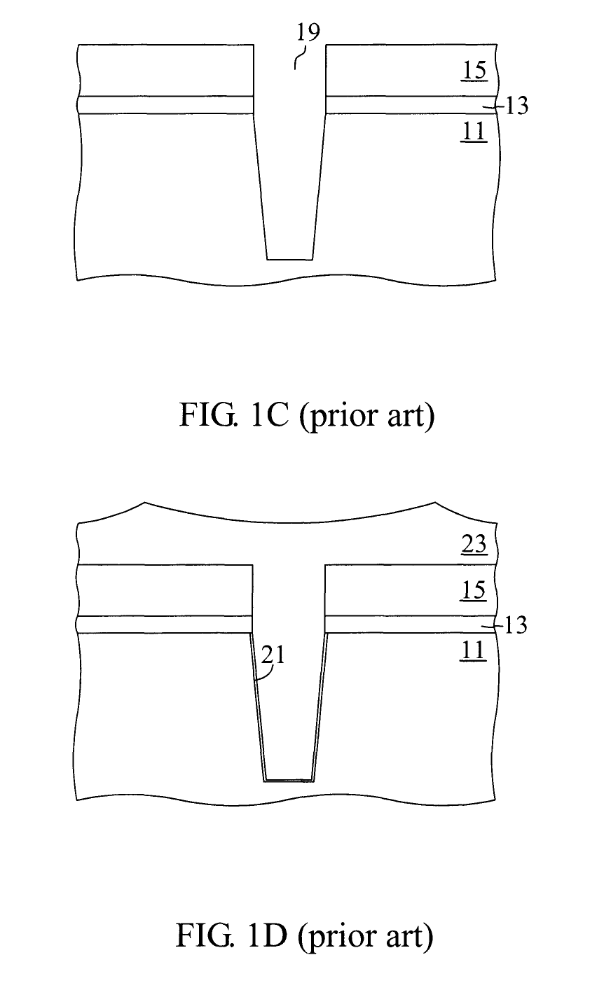

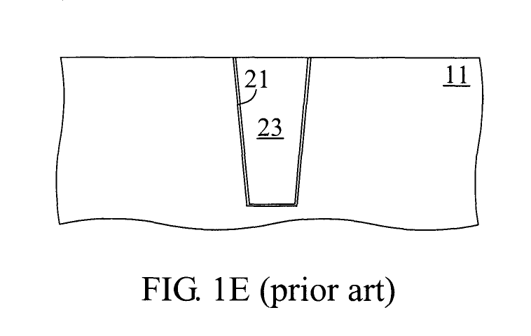

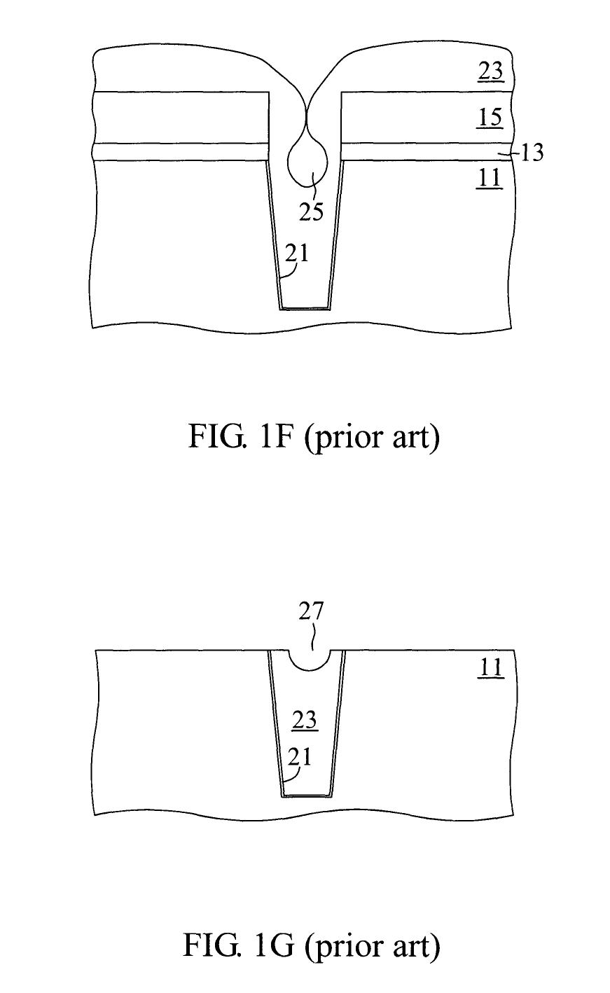

### DESCRIPTION OF THE PREFERRED EMBODIMENT

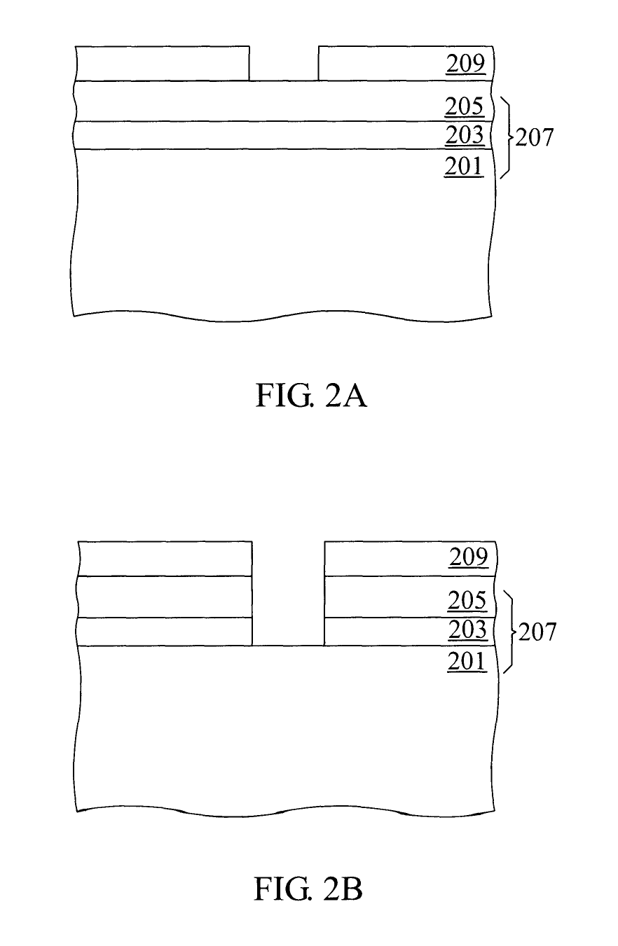

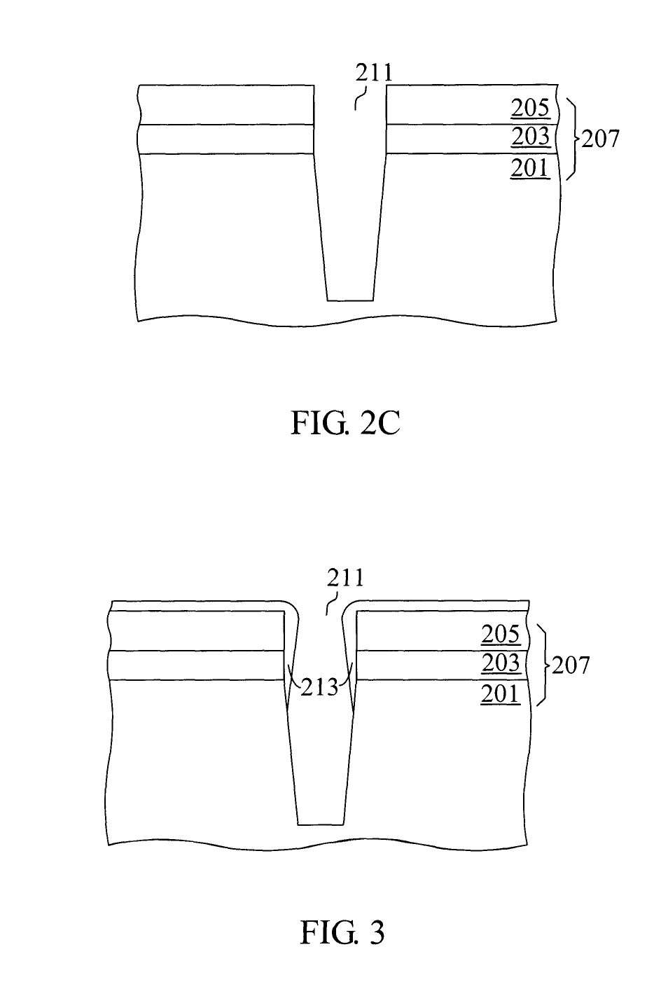

First, a substantially “v” shaped trench is formed within a substrate using any appropriate known method, wherein the shape of the trench is not limited to the v-shape and can be a v-shape or a similar shape. As shown in FIG. 2A, a pad oxide layer 203 and a pad nitride layer 205 are sequentially formed on the base layer 201 to provide a substrate 207 (i.e. the substrate 207 has a base layer 201, a pad oxide layer 203, and a pad nitride layer 205). The method for forming the pad oxide layer 203 can include (but is not limited to) the following steps: a thermal oxidation process is conducted on the base layer 201 at a suitable temperature in a water-free and oxygen-rich environment. The pad nitride layer 205 is provided using (but is not limited to) LPCVD. The total thickness of the pad oxide layer 203 and the pad nitride layer 205 usually ranges from 80 to 200 nm, preferably from 90 to 120 nm, such as 100 nm.

Then, a patterned photoresist layer 209 with an active area pattern is formed onto the substrate 207 using such as a photolithography process. For example, a layer of photo-sensitive material, called the photo-resist layer is applied to cover the surface of the substrate 207. A portion of the photo-resist layer is then exposed to light through a mask. Herein, the photo-resist layer is selectively exposed because of the mask with the active area pattern. Thus, the active area pattern is completely transmitted to the photo-resist layer. Lastly, a portion of the photo-sensitive material is removed using a suitable developer so that the active area pattern can appear on the photo-resist layer. As a result, a patterned photo-resist layer 209 with an active area pattern on the substrate 207 is formed.

As shown in FIG. 2B, a portion of both the pad oxide layer 203 and pad nitride layer 205, which are not protected by the patterned photo-resist layer 209, are removed to expose a portion of the base layer 201 using a suitable etching process, such as anisotropic dry etching with a fluoride plasma. Then, the patterned photo-resist layer 209 on the substrate 207 is removed using an ashing process, which normally uses an oxygen plasma and a suitable etchant. There are other methods that can be used for conducting the ashing process, such as using ozone plasma with a fluorine-containing gas.

Next, as shown in FIG. 2C, a suitable etching process, such as a dry etching process, is performed to remove a portion of the base layer 201 to form a “v” shaped trench 211 with a suitable depth within the exposed portion of the base layer 201. The depth of the trench 211, metered from the surface of the base layer 201 to the bottom of the trench 211, generally ranges from 200 to 300 nm, preferably from 200 to 250 nm, such as about 220 nm.

FIG. 3 illustrates a non-conformal deposition with poor step coverage, in which a first dielectric layer 213, which covers the upper portion of the inner wall of the trench 211 and the substrate 207, is formed using a suitable process that controls the deposition conditions, such as (but is not limited to) a plasma-enhanced chemical vapor deposition (PECVD) with a suitable material, such as tetraethoxysilane (TEOS). The first dielectric layer 213 is usually an oxide layer, but can also be a polymer or other dielectric material. The first dielectric layer 213 on the substrate 207 usually has a thickness ranging from 10 to 30 nm, preferably 15 to 25 nm, such as about 20 nm.

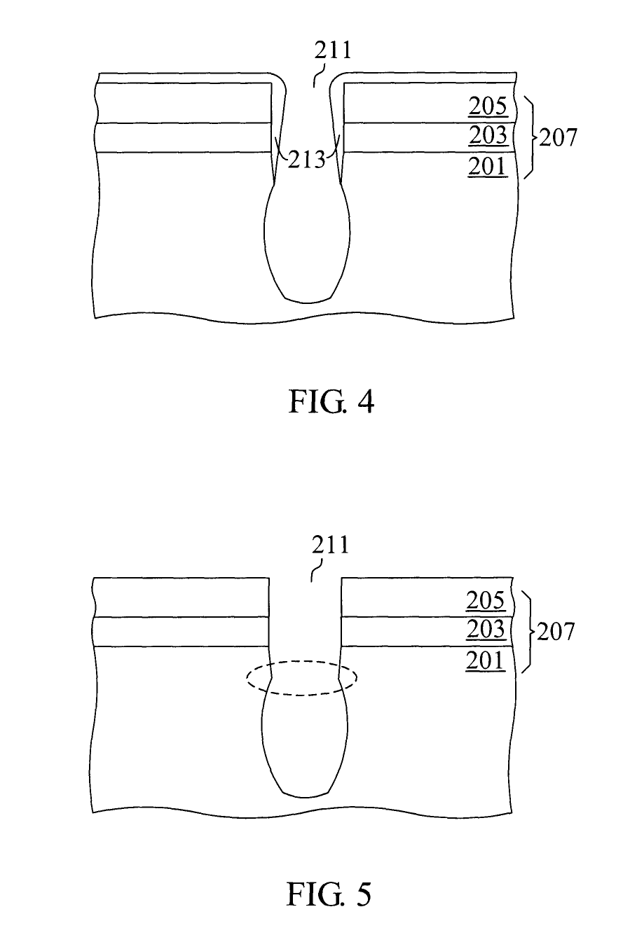

Following, as shown in FIG. 4, a first etching process is performed to pull back a portion of the inner wall of the trench 211, which is not covered by the first dielectric layer 213. In particular, a portion of the base layer 201, which is not covered by the first dielectric layer 213 within the lower portion of trench 211, is removed using a first etching process to pull back the inner wall of the trench 211. The first etching process can be, for example, a wet etching process in which an etchant with ammonia is used at a suitable temperature ranging from 55 to 75° C. However, a portion of the first dielectric layer 213 is probably still deposited in an undesirable region such as the lower portion of the inner wall of the trench 211 during the step shown in FIG. 3. In this case, that portion of the first dielectric layer 213 influences the result of the first etching process. Thus, a second etching process can be performed prior to the first etching process to remove the undesirable first dielectric layer 213, which is deposited within the trench but not on the upper portion of the inner wall of the trench 211. Again, the second etching process can be a wet etching process but is not limited to this example. If the material of the base layer 201 and the first dielectric layer 213 are respectively silicon and silicon oxide, a second etchant containing hydrogen fluoride can be used to remove the first dielectric layer 213 deposited on the lower portion of the inner wall of the trench 211. Thereafter, the first etching process can be performed as described hereinbefore.

FIG. 5 illustrates a third etching process that is performed to completely remove the first dielectric layer 213 to form a waist, as marked with the dotted line in the figure. The waist has a width narrower than that of the opening of the trench 211, and is located at the border between the upper and the lower portions of the trench 211. For this purpose, the third etching process can be either a dry etching process, or a wet etching process performed using a suitable etchant containing such as hydrogen fluoride as the third etchant.

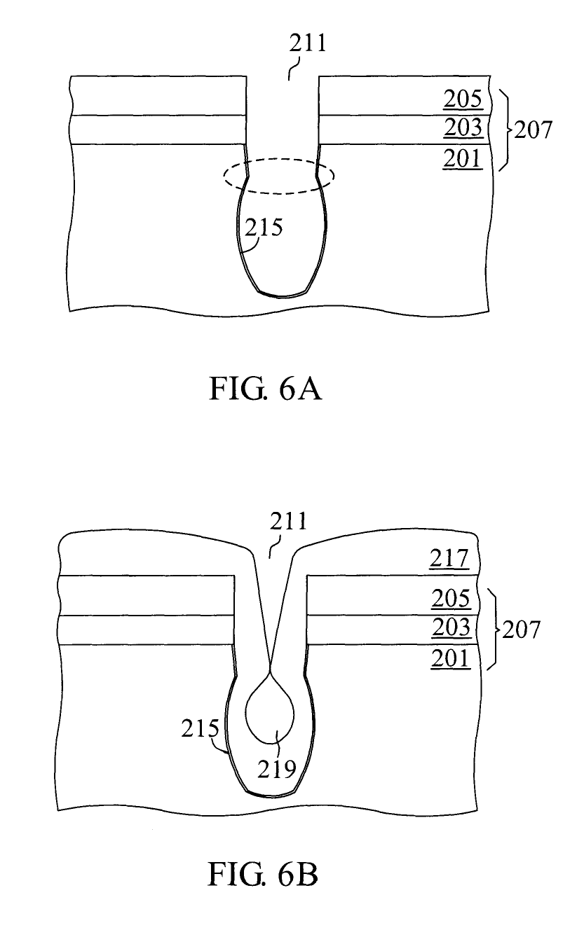

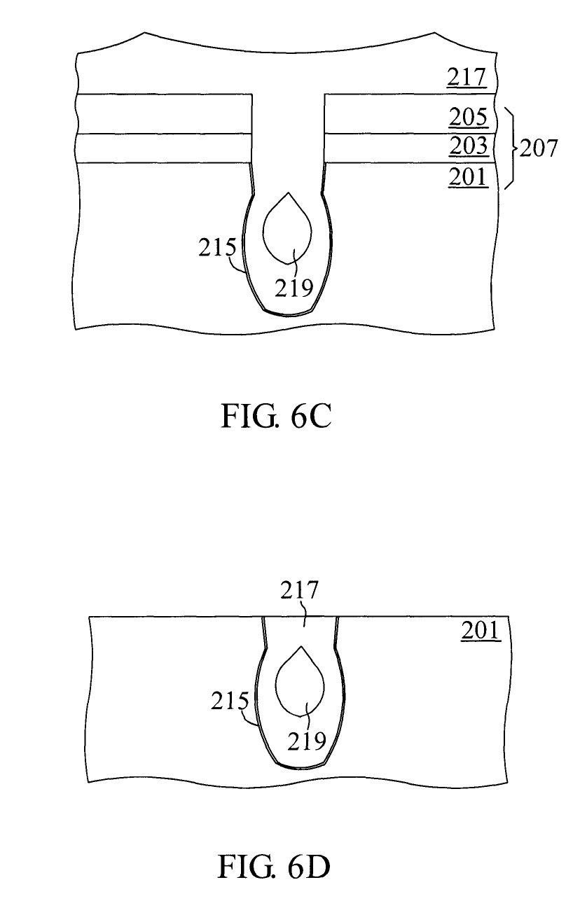

Finally, a trench filling process is performed. A thin oxide layer, called a liner oxide, can be optionally formed on the inner wall of the trench. The process for forming the thin oxide layer is illustrated below as an example. As shown in FIG. 6A, a suitable process, such as a thermal oxidation process, is first conducted to form a liner oxide 215 on the inner wall of the trench 211. In addition, as shown in FIG. 6B, a dielectric material, such as silicon oxide, is deposited onto the substrate 207 using a suitable deposition method. The dielectric material covers the opening of the trench 211 to form a second dielectric layer 217. Since the width of the waist is relatively small, the dielectric material deposited on the inner wall of the trench 211 gradually comes into contact with the waist. As a result, the lower portion of the trench is blocked off during the process for depositing the dielectric material. A void 219 is consequently formed in the lower portion of the trench. The second dielectric layer 217, such as a silicon oxide layer, can be formed using any of the following methods: a high density plasma CVD process, a low pressure CVD method with TEOS, a Semi-Atmospheric Pressure CVD with ozone/TEOS or any other suitable CVD methods.

After the lower portion of the trench 211 is closed, as shown in FIG. 6C, the upper portion of the trench can be treated as a small trench with a small aspect ratio. As the trench filling process is continually performed, the quality of the trench filling is relatively fine and no unnecessary void is formed within the upper portion of the trench 211. Thereby, a void 219, which can release the stress, is formed inside the trench 211. The opening of the trench 211 is covered by the second dielectric layer 217 after the trench filling process. Finally referring to FIG. 6D, a process, such as the CMP process, is performed to remove the unnecessary portions of the second dielectric layer 217 and a suitable etching process, such as a wet etching, is then performed to remove the pad oxide layer 203 and the pad nitride layer 205. Then, a shallow trench isolation structure is obtained.

A shallow trench isolation structure is formed in the base layer 201 using the aforementioned steps. A trench 211 with a waist whose width is narrower than that of the opening of the trench 211 within the base layer 201 is formed, while a dielectric material (i.e. the above-mentioned second dielectric layer 217) covers the opening of the trench 211, creating a void 219 inside the trench 211 below the waist.

Thus, the present invention efficiently forms a void in the lower portion of the trench to release stress. The invention does this by providing a trench with a waist whose width is narrower than that of the opening of the trench. The invention also avoids the short circuiting between the word lines due to the relatively fine quality of trench filling the upper portion of the trench. As a result, no hole is formed on the surface of the shallow trench isolation structure.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

1. A method for forming a shallow trench isolation structure comprising the following steps:
providing a substrate;
forming a “v” shaped trench within the substrate;
forming a first dielectric layer to cover the upper portion of the inner wall of the trench;
conducting a first etching process to pull back the inner wall, uncovered by the first dielectric layer, of the trench;
removing the first dielectric layer; and
forming a second dielectric layer to cover the trench and to form a void inside the trench.

2. The method as claimed in claim 1, wherein the substrate comprises the following layers from bottom to top: a base layer, a pad oxide layer, and a pad nitride layer.

3. The method as claimed in claim 1, wherein the step of forming the first dielectric layer includes conducting a non-conformal deposition.

4. The method as claimed in claim 3, wherein the non-conformal deposition is a plasma-enhanced chemical vapor deposition.

5. The method as claimed in claim 3, wherein the non-conformal deposition is a chemical vapor deposition with tetraethoxysilane.

6. The method as claimed in claim 1, wherein a first etchant containing ammonia is used during the first etching process.

7. The method as claimed in claim 6, wherein the first etching process is conducted at a temperature ranging from 55 to 75° C.

8. The method as claimed in claim 1 further comprising conducting a second etching process before the first etching process, to remove the first dielectric layer inside the trench but not on the upper portion of the inner wall of the trench.

9. The method as claimed in claim 8, wherein a second etchant containing hydrofluoric acid is used during the second etching process.

10. The method as claimed in claim 1, wherein the step of removing the first dielectric layer includes a dry etching operation.

11. The method as claimed in claim 1, wherein the step of removing the first dielectric layer includes conducting an etching operation with a third etchant containing hydrofluoric acid.

12. The method as claimed in claim 1, wherein the step of forming the second dielectric layer includes conducting a high density plasma chemical vapor deposition.

13. The method as claimed in claim 1 further comprising forming an oxide layer on the inner wall of the trench prior to the step of forming the second dielectric layer.

14. The method as claimed in claim 1, wherein the first dielectric layer is an oxide layer.

15. The method as claimed in claim 1, wherein the first dielectric layer on the substrate has a thickness ranging from 10 to 30 nm, preferably from 15 to 25 nm.

16. The method as claimed in claim 1, wherein the second dielectric layer is an oxide layer.

17-23. (canceled)
